(19) United States
(12) Patent Application Publication
(10) Pub. No.: US 2006/0049142 A1
(43) Pub. Date: Mar. 9, 2006

(54) Apparatus and method for polishing semiconductor wafer

(75) Inventor: Fumitaka Ito, Nagaokakyo-shi (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., Osaka (JP)

(21) Appl. No.: 11/200,172

(22) Filed: Aug. 10, 2005

(30) Foreign Application Priority Data
Sep. 7, 2004 (JP) 2004-259692

(51) Int. Cl. C03C 15/00; H01L 21/306; B44C 1/22

(52) U.S. Cl. 216/88; 438/692; 156/345.12

(57) ABSTRACT

By almost completely removing foreign matter adhering to the wafer holding unit of a polishing head in a CMP process, a wafer yield is improved. An apparatus for polishing a semiconductor wafer is provided with a wafer holder to which the wafer is attached, a polishing unit which polishes the wafer with a polishing slurry supplied to the wafer, a wafer attaching and detaching unit at which the wafer is attached to or detached from the wafer holder, and a washing unit which washes the wafer holder. The wafer holder has a wafer contact surface, which contacts the backside of the wafer, and a supporting unit which prevents the jump out of the wafer. The washing unit has nozzles which supply a washing solution to the wafer contact surface and the supporting unit, and the nozzles are composed of a plurality of outlets capable of supplying at least two different liquids. As a result, it is possible to almost completely remove the foreign matter adhering to the wafer holder to always keep the wafer holder clean.

### BACKGROUND OF THE INVENTION

1. Field of the Invention

The present invention relates to a polishing apparatus used in a planarization process such as chemical mechanical polishing (CMP) performed in the manufacture of, for instance, a silicon semiconductor substrate and, in particular, to an apparatus for polishing a semiconductor wafer, which has a washing unit that washes a polishing carrier head contacting the rear surface of a semiconductor substrate according to a method for washing the polishing carrier head, and to a method for polishing the semiconductor wafer.

2. Background Art

When the surfaces of flat workpieces such as silicon semiconductor substrates are planarized, CMP (chemical mechanical polishing) machines are now used (see, for example, JP-A Nos. 11-320385, 12-263420, and 7-223142).

FIG. 6 is a schematic diagram of a conventional CMP apparatus. This CMP apparatus includes a wafer polishing unit 20, a wafer loading and unloading (L and UL) unit, a polishing head washing unit 7. A polishing head 4 is washed at the polishing head washing unit 7 when a wafer 1 is not held by the polishing head 4. The wafer 1, which is a workpiece to be polished, is attached to or detached from the polishing head 4 at the wafer L and UL unit. Furthermore, the wafer L and UL unit may be provided with the washing unit 7 which washes the polishing head 4. The polishing head 4 holding the wafer 1 is allowed to move between these units. With the wafer polishing unit 20, the polishing head 4 holding the wafer 1 (workpiece to be polished) on its undersurface is positioned oppositely above a table (platen) 2. To the upper surface of the table 2, a polishing cloth (polishing pad) 3 is adhered.

In such a CMP apparatus, the frontside of the wafer 1 is polished in a manner that a slurry (abrasive) is supplied onto the polishing cloth 3 via a slurry (abrasive) supply nozzle 6 while rotating the table 2, and then the wafer 1 is pressed against the polishing cloth 3 by using the polishing head 4 while rotating the wafer 1. To fix and hold the wafer 1 to the polishing head 4 so as not to jump out during its polishing, a retainer ring (guide ring) 8 is attached to the polishing head 4. As materials for the retainer ring 8, engineering plastics such as Teflon and PPS are used. The wafer polishing is sometimes performed in a state in which the retainer ring 8 is pressed against the polishing cloth 3.

The wafer contact surface 5 of the polishing head 4 which holds the wafer 1 is in contact with the backside of the wafer 1 during the polishing. As materials for the wafer contact surface 5 of the polishing head 4, hard or soft materials are used. With the hard materials, there are SUS materials, alumina ceramics, and the like. The wafer contact surface 5 of the polishing head 4 made of such a hard material is called a top ring and so on, and in a state in which the wafer contact surface 5 of the polishing head 4 directly holds the backside of the wafer 1 through vacuum suction or the like, the frontside of the wafer 1 is polished. With the soft materials, there are silicon rubber film, neoprene rubber film, and the like, and they are called membranes, backing pads (which are made of plastic thin film on which rubber is vapor-deposited), and so on. The wafer contact surface 5 of the polishing head 4 made of such a soft material holds the backside of the wafer 1 through water filling suction, vacuum suction, or the like during the polishing of the frontside of the wafer 1.

### SUMMARY OF THE INVENTION

As the wafer 1 is repeatedly polished on the polishing cloth 3 while the wafer 1 is held by the polishing head 4 and the slurry (abrasive) is supplied, fine particles such as polishing dust (polishing products), abrasive grains included in the slurry (abrasive) gradually adhere to the wafer contact surface 5 of the polishing head 4 and to the retainer ring 8. Because of this, the foreign matter adhering to the wafer contact surface 5 of the polishing head 4 is transferred to the backside of the wafer 1 during polishing, so that the backside of the wafer 1 is contaminated excessively. As a result, in the CMP process step, there has been the problem that the ability to remove the particles on the backside of the wafer 1 (washing ability) is reduced during the washing after the CMP. Besides, there has been the problem that the transfer of the particles on the backside of the wafer 1 to the frontside of the wafer 1 reduces the ability to remove the particles on the frontside of the wafer 1 (washing ability) during the washing after the CMP. Further, there has been the problem that when the wafer 1 is polished in a state in which the foreign matter is sandwiched between the backside of the wafer 1 and the wafer contact surface 5 of the polishing head 4, abnormal polishing (bull's-eyes) occurs only in places of the frontside of the wafer 1 immediately under which the foreign matter is present. Still further, the dropping of the foreign matter adhering to the retainer ring 8 onto the polishing cloth 3 during the polishing has caused scratches on the frontside of the wafer 1. To solve these problems, it is necessary to wash the wafer contact surface 5 of the polishing head 4 and the retainer ring 8 to always keep them clean.

FIG. 7 is a schematic diagram of a conventional polishing head washing mechanism. With a method for washing a polishing head 4, the wafer contact surface 5 of the polishing head 4 and a retainer ring 8 are dipped in DIW (deionized water) supplied via a DIW line 25 or take a shower of DIW; however, their effect of removing the adhering foreign matter has been small. As a result, the operating efficiency of the CMP apparatus has been reduced by performing additional washing of the polishing head 4 or maintenance including the cleaning of the wafer holding unit of the polishing head 4 and of the retainer ring 8 through the removal of the polishing head 4 from the CMP apparatus and their exchange.

In these conventional techniques, the foreign matter, such as the polishing dust (polishing products) and the abrasive grains included in the slurry (abrasive), adhering to the wafer contact surface of the polishing head and the retainer ring cannot be removed completely, so that the adhering foreign matter is transferred to the backside of the wafer to cause such a contamination; therefore, there is apprehension that the ability to remove the particles on the backside of the wafer (washing ability) during the washing after the CMP is reduced. Also, when both sides of the wafer are brush-washed during the washing after the CMP, there is apprehension that the ability to remove the particles on the frontside of the wafer (washing ability) is reduced by the transfer of the particles exfoliating from the backside of the wafer to the frontside of the wafer. Besides, when the wafer is polished in a state in which the adhering foreign matter is sandwiched between the backside of the wafer and the wafer contact surface of the polishing head, there is apprehension that abnormal polishing (bull's eyes) occurs only in places of the frontside of the wafer immediately under which the foreign matter is present. Further, since the foreign matter adhering to the retainer ring drops onto the polishing cloth during the polishing, there is apprehension that scratches occur on the frontside of the wafer. Still further, when the particles remain on the backside of the wafer after the CMP step, there is apprehension that out-of-focus photolithography is induced in a post-CMP step. Furthermore, there is apprehension that particle cross-contamination is caused to semiconductor manufacturing equipment used in a process step after the CMP step. As a result of these problems, device defects such as leaks and short circuits between wirings are caused.

Although those problems resulting from the particles on the backside of the wafer had been tolerated, they have not become negligible at present as LSI circuits have had much finer patterns in recent years.

The present invention is provided in view of those problems with the washing mechanism for the wafer holding unit of the conventional CMP apparatus and with the washing method in which the washing mechanism is used; that is, it is an object of the invention to provide an apparatus for polishing a semiconductor wafer, which is capable of effectively washing the wafer holding unit (wafer contact surface and retainer ring) of a polishing head to always keep the wafer holding unit clean through the provision of a washing mechanism which almost completely removes foreign matter adhering to the wafer holding unit in a CMP process step, and a polishing method in which the polishing apparatus is used.

To attain such an object, An apparatus for polishing a semiconductor wafer according to a first invention is provided with a wafer holder which holds a wafer, a polishing unit which polishes the wafer with a polishing slurry supplied to the wafer, a wafer attaching and detaching unit which attaches or detaches the wafer to or from the wafer holder, and a washing unit which washes the wafer holder. The wafer holder has a wafer contact surface, which contacts the backside of the wafer, and a supporting unit which prevents the jump out of the wafer. The washing unit has nozzles which supply a washing solution to the wafer contact surface and the supporting unit. The nozzles are composed of a plurality of outlets which supply at least two different liquids.

According to such a structure, the washing unit can be provided with a chemical washing (chemical solution washing) mechanism, so that it is possible to almost completely remove the foreign matter adhering to the wafer holder to always keep the wafer holder clean.

Because of this, the ability to wash the backside of the wafer can be improved; hence, the occurrence of out-of-focus photolithography, abnormal polishing, and scratches is prevented by reducing residual particles on the backside of the wafer and residual particles on the frontside of the wafer resulting from the residual particles on the backside, and then, as effects of these results, not only device defects, such as leaks and short circuits between wirings, are prevented, but a wafer yield is improved. Besides, particle cross-contamination to an apparatus used in a post-CMP process step is prevented. Further, the washing cost of the wafer can be reduced by omitting a post-CMP washing process and washing process in its subsequent process and by reducing a load on the polishing apparatus. Still further, maintenance activities for the polishing head can be simplified by the adoption of a prolonged period between the maintenance activities and the use of an extended-life expendable polishing head material; hence, by these effects, it is expected that CoO (Cost of Ownership) is reduced.

An apparatus for polishing a semiconductor wafer according to a second invention has a wafer holder to which a wafer is attached, a polishing unit which polishes the wafer with a polishing slurry supplied to the wafer, a wafer attaching and detaching unit which attaches or detaches the wafer to or from the wafer holder, and a washing unit which washes the wafer holder. The wafer holder has a wafer contact surface, which contacts the backside of the wafer, and a supporting unit which prevents the jump out of the wafer. The washing unit is provided with nozzles, which supply a washing solution to the wafer contact surface and the supporting unit, and component which physically washes the wafer contact surface and the supporting unit.

According to this construction, the washing unit can be provided with a chemical washing (chemical solution washing) mechanism and a physical washing (ultrasonic washing, brush washing, etc.) mechanism, so that it is possible to almost completely remove foreign matter adhering to the wafer holder to always keep the wafer holder clean. As a result, the same effects as those described in the first invention can be achieved.

An apparatus for polishing a semiconductor wafer according to a third invention is the apparatus for polishing a semiconductor wafer according to the first invention whose washing unit is provided in the wafer attaching and detaching unit.

An apparatus for polishing a semiconductor wafer according to a fourth invention is the apparatus for polishing a semiconductor wafer according to the second invention whose washing unit is provided in the wafer attaching and detaching unit.

An apparatus for polishing a semiconductor wafer according to a fifth invention is the apparatus for polishing a semiconductor wafer according to the first invention whose washing solution is composed of water and a chemical solution.

An apparatus for polishing a semiconductor wafer according to a sixth invention is the apparatus for polishing a semiconductor wafer according to the second invention whose washing solution is composed of water and a chemical solution.

An apparatus for polishing a semiconductor wafer according to a seventh invention is the apparatus for polishing a semiconductor wafer according to the first invention whose washing solution is the chemical solution which lies in the same pH range or has the same pH value as the polishing slurry.

An apparatus for polishing a semiconductor wafer according to an eighth invention is the apparatus for polishing a semiconductor wafer according to the second invention whose washing solution is the chemical solution which lies in the same pH range or has the same pH value as the polishing slurry.

An apparatus for polishing a semiconductor wafer according to a ninth invention is the apparatus for polishing a semiconductor wafer according to the first invention whose nozzles concentrically supply the washing solution to the wafer contact surface of the wafer holder.

An apparatus for polishing a semiconductor wafer according to a tenth invention is the apparatus for polishing a semiconductor wafer according to the second invention whose nozzles concentrically supply the washing solution to the wafer contact surface of the wafer holder.

An apparatus for polishing a semiconductor wafer according to an eleventh invention is the apparatus for polishing a semiconductor wafer according to the second invention whose physical washing component of the washing unit is an ultrasonic oscillation mechanism, a brush washing mechanism, a high-pressure spray mechanism, or a megasonic oscillation mechanism.

A method for polishing a semiconductor wafer according to a twelfth invention is a method for polishing a semiconductor wafer in which a wafer holder to which the wafer is attached moves between a wafer attaching and detaching unit and a washing unit via a polishing unit to polish the semiconductor wafer and to wash the wafer holder. The method for polishing a semiconductor wafer according to the twelfth invention includes a step of attaching the wafer to the wafer holder at the wafer attaching and detaching unit and of conveying the wafer to the polishing unit, a step of polishing the wafer with the polishing unit, moving the wafer to the wafer attaching and detaching unit, and detaching the wafer from the wafer holder, and a step of moving the wafer holder, from which the wafer has been detached, to the washing unit and of washing the wafer holder with at least two different liquids supplied. According to the structure, the same effects as those described in the first invention can be achieved.

A method for polishing a semiconductor wafer according to a thirteenth invention is the method for polishing a semiconductor wafer according to the twelfth invention in which the washing unit washes the wafer holder through the use of an ultrasonic oscillation mechanism, a brush washing mechanism, a high-pressure spray mechanism, or a megasonic oscillation mechanism.

A method for polishing a semiconductor wafer according to a fourteenth invention is the method for polishing a semiconductor wafer according to the thirteenth invention in which places washed by the ultrasonic wave of the ultrasonic oscillation mechanism, the brush of the brush washing mechanism, the high-pressure spray of the high-pressure spray mechanism, or the megasonic vibration of the megasonic oscillation mechanism are each concentrically selected to the wafer contact surface of the wafer holder.

A method for polishing a semiconductor wafer according to a fifteenth invention is the method for polishing a semiconductor wafer according to the twelfth invention in which the washing process is performed immediately before the attachment of the wafer or immediately after the detachment of the wafer. Thus, as for timing in washing the wafer holder, the washing can be performed immediately before every wafer loading or immediately after every wafer unloading.

A method for polishing a semiconductor wafer according to a sixteenth invention is the method for polishing a semiconductor wafer according to the twelfth invention in which the number of times the washing process is performed is determined according to the number of times the wafer holder is attached or detached or to a time period in which the wafers are polished. Thus, as for timing in washing the wafer holder, it is also possible to perform the washing according to the number of times the wafer loading or the wafer unloading is performed and to the time period in which the wafers are polished.

A method for polishing a semiconductor wafer according to a seventeenth invention is the method for polishing a semiconductor wafer according to the twelfth invention in which the washing process is performed during the idling of the polishing apparatus. Thus, as for timing in washing the wafer holder, it is also possible to periodically perform the washing during the idling of the polishing apparatus.

### BRIEF DESCRIPTION OF THE DRAWINGS

FIG. 1 is a schematic diagram of a polishing head washing unit according to a first embodiment of the present invention;

FIG. 2 is a schematic diagram of a polishing head washing unit according to a second embodiment of the invention;

FIG. 3 is a schematic diagram of a polishing head washing unit according to a third embodiment of the invention;

FIG. 4 is a schematic diagram of a polishing head washing unit according to a fourth embodiment of the invention;

FIG. 5 is a schematic diagram of a polishing head washing unit according to a fifth embodiment of the invention;

FIG. 6 is a schematic diagram of a typical CMP apparatus; and

FIG. 7 is a schematic diagram of a conventional polishing head washing apparatus.

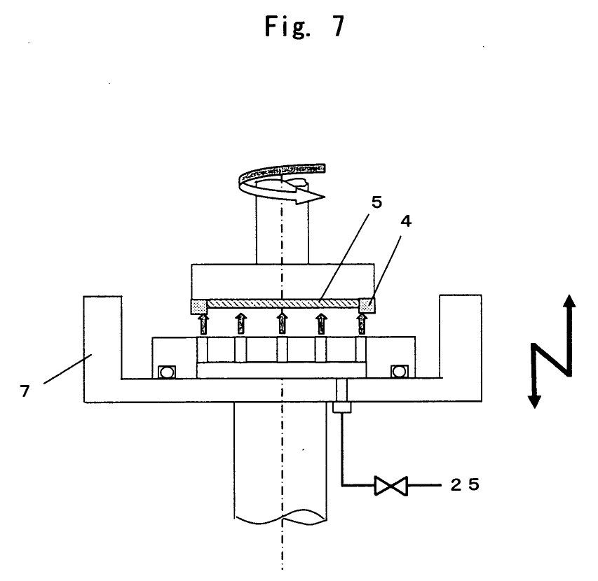

### DESCRIPTION OF THE PREFERRED EMBODIMENTS

Embodiments indicating the schematic structure of a polishing head washing unit included in a polishing apparatus according to the present invention will be described below.

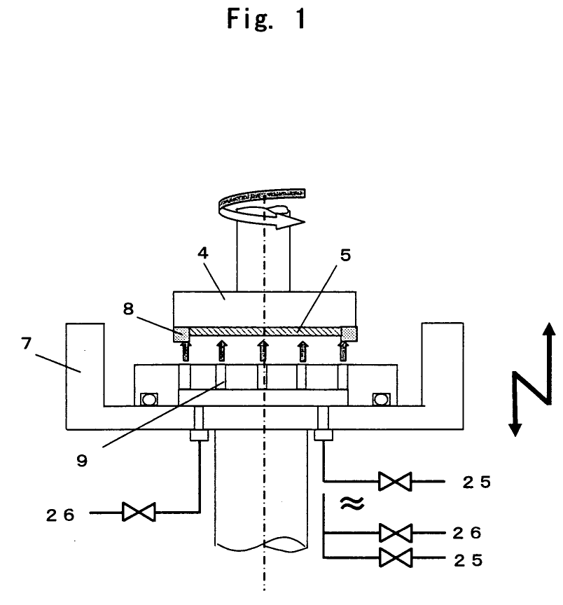

To begin with, a first embodiment of the invention will be described with reference to FIG. 1. FIG. 1 is a schematic diagram of the polishing head washing unit according to the first embodiment of the invention, and the unit is provided with not only a conventional polishing head washing mechanism but an additional chemical solution supply mechanism.

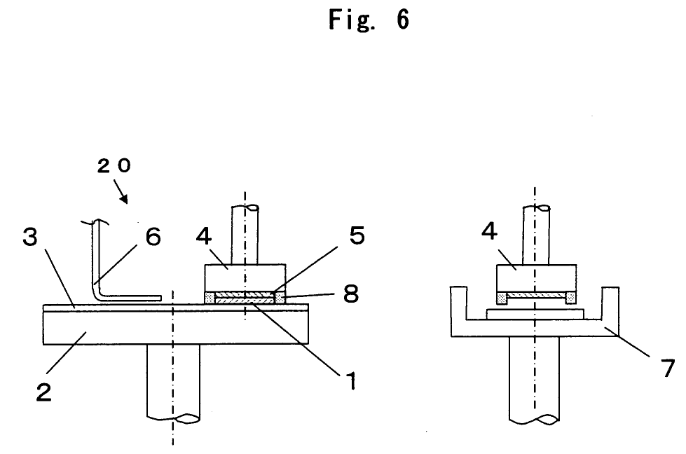

Like the CMP apparatus shown in FIG. 6, the polishing apparatus according to the first embodiment of the invention is provided with a wafer holder (polishing head) 4 to which a wafer 1 is attached and which moves from unit to unit, a polishing unit (wafer polishing unit) 20 which polishes the wafer 1 while supplying a polishing slurry, a wafer attaching and detaching unit by which the wafer 1 is attached to or detached from the polishing head 4, and a washing unit 7 which washes the polishing head 4. As shown in FIG. 1, the polishing head 4 has a wafer contact surface 5, which contacts the backside of the wafer 1, and a supporting unit (retainer ring) 8 which prevents the jumping out of the wafer 1. The washing unit 7 has nozzles (spray nozzles) 9 which supplies a washing liquid to the wafer contact surface 5 and the retainer ring 8. The spray nozzles 9 are composed of a plurality of outlets which are capable of supplying at least two different liquids. In this case, the spray nozzles 9 are not only provided free-movably so as to be able to be fixed at any positions in the washing unit 7 but formed so as to communicate with DIW lines 25 and chemical solution lines 26 via the washing unit 7. Also, the washing unit 7 is provided within the wafer attaching and detaching unit.

Next, a method for washing the polishing head of the polishing apparatus will be described.

The polishing head 4 moves to the polishing head washing unit 7 before wafer loading or after wafer unloading. At this time, the wafer 1 is attached to the polishing head 4 at the wafer attaching and detaching unit and then conveyed to the polishing unit 20. After the polishing of the wafer 1 at the polishing unit 20, the wafer 1 is moved to the wafer attaching and detaching unit and then removed from the polishing head 4. After the removal of the wafer 1, the polishing head 4 is moved to the washing unit 7, following which the rear surface of the polishing head 4 is covered with the polishing head washing unit 7 by lowering the polishing head 4 or raising the polishing head washing unit 7. Then the rear surface of the polishing head 4 is washed by supplying the DIW and the chemical solution from the spray nozzles 9 of the polishing head washing unit 7 immediately under the polishing head 4 to the rear surface of the polishing head 4 while rotating the polishing head 4.

The number of revolutions of the polishing head 4, the timing of the supplies of the DIW and the chemical solution, and the washing time of the polishing head 4 can be set freely as in the case of the polishing recipe of the CMP apparatus. Also, it is possible to set the spray nozzles 9 of the polishing head washing unit 7 to any positions, thereby the bottom surface of the polishing head 4 can be washed at the concentrically selected places thereof. In addition, by pouring the chemical solution into the polishing head washing unit 7, chemical solution washing can also be performed in a state in which the polishing head 4 is dipped in the chemical solution. It is desirable that the chemical solution used for the washing lie in the same pH range or have the same pH value as the polishing slurry. After the washing, the polishing head 4 is brought into a stand-by state before the wafer loading or after the wafer unloading by raising the polishing head 4 or lowering the washing unit 7. By performing such a washing step, foreign matter adhering to the bottom surface of the polishing head 4 is removed.

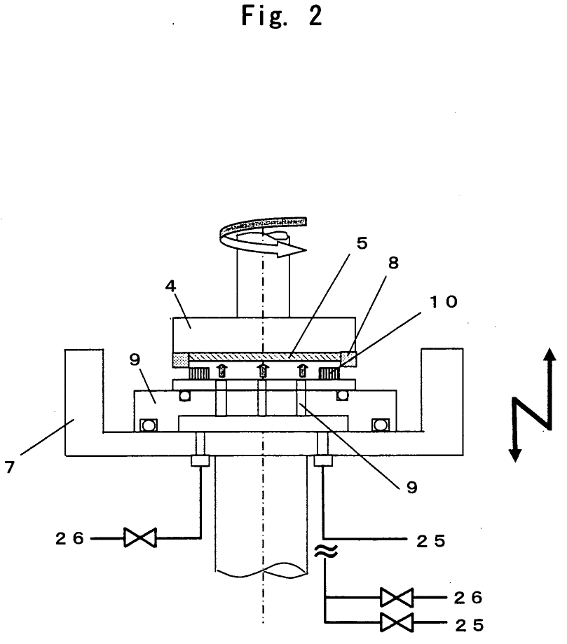

A second embodiment of the invention will be described with reference to FIG. 2. FIG. 2 is a schematic diagram of a polishing head washing unit according to the second embodiment of the invention. The washing unit is provided with not only the conventional polishing head washing mechanism but an additional washing mechanism using brushes 10.

Unlike the first embodiment of the invention, the washing unit 7 is provided with the brushes 10 as components which physically wash the wafer contact surface 5 and the retainer ring 8. The brushes 10 can be fixed at any positions. The other structure of the polishing head washing unit according to the second embodiment is the same as that described in the first embodiment, and the description of the same components as those described in the first embodiment will be omitted instead of giving the same reference numerals.

As for a method for washing the polishing head, like the washing method described in the first embodiment, the polishing head 4 is moved to the polishing head washing unit 7 before the wafer loading or after the wafer unloading. Thereafter, by lowering the polishing head 4 or raising the polishing head washing unit 7, the bottom surface of the polishing head 4 is brought into contact with the brushes 10 and is covered with the polishing head washing unit 7. Next, the DIW is supplied to the brushes 10 while rotating the polishing head 4 to wash the bottom surfaces of the polishing head 4. Like FIG. 1, it is also possible to supply the chemical solution in addition to the DIW. The number of revolutions of the polishing head 4, the timing of the supplies of the DIW and the chemical solution, and the washing time of the polishing head 4 can be set freely as in the case of the polishing recipe of the CMP apparatus. Also, it is possible to set the spay nozzles 9 and the brushes 10 of the polishing head washing unit 7 to any positions, thereby the bottom surface of the polishing head 4 can be washed at the concentrically selected places thereof. In addition, by pouring the DIW and the chemical solution into the polishing head washing unit 7, brush washing can be performed in a state in which the polishing head 4 is dipped in the chemical solution. It is desirable that the chemical solution used for the washing lie in the same pH range or have the same pH value as the polishing slurry. After the washing, the polishing head 4 is brought into a stand-by state before wafer loading or after wafer unloading by raising the polishing head 4 or lowering the washing unit 7. By performing such a washing step, foreign matter adhering to the bottom surface of the polishing head 4 is removed.

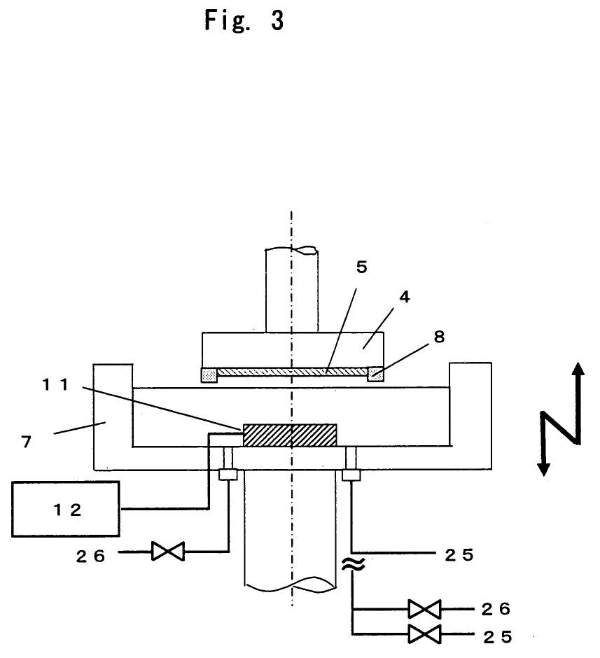

A third embodiment of the invention will be described with reference to FIG. 3. FIG. 3 is a schematic diagram of a polishing head washing unit according to the third embodiment of the invention. The washing unit is provide with not only the conventional polishing head washing mechanism but an additional ultrasonic washing mechanism (ultrasonic oscillation mechanism).

Unlike the first embodiment of the invention, the washing unit 7 is provided with the ultrasonic oscillation mechanism as a component which physically washes the wafer contact surface 5 and the retainer ring 8. The ultrasonic oscillation mechanism includes an ultrasonic vibrator 11 placed in the washing unit 7 and an oscillator 12 connected to the vibrator 11. Like FIG. 1, it is also possible to supply the chemical solution in addition to the DIW. The other structure of the polishing head washing unit according to the third embodiment is the same as that described in the first embodiment, and the description of the same components as those described in the first embodiment will be omitted instead of giving the same reference numerals.

As for a method for washing the polishing head, the DIW or the chemical solution is initially poured into the polishing head washing unit 7. Like the first embodiment, the polishing head 4 is moved to the polishing head washing unit 7 before wafer loading or after wader unloading. Thereafter, by lowering the polishing head 4 or raising the polishing head washing unit 7, the bottom surface of the polishing head 4 is dipped in the DIW or the chemical solution within the polishing head washing unit 7 while covered with the polishing head washing unit 7, following which ultrasonic washing is performed by vibrating the ultrasonic vibrator 11 through the use of the oscillator 12. The washing time of the polishing head 4 can be set freely as in the case of the polishing recipe of the CMP apparatus. It is desirable that the chemical solution used for the washing lie in the same pH range or have the same pH value as the polishing slurry. After the polishing, the polishing head 4 is brought into a stand-by state before wafer loading or after wafer unloading by raising the polishing head 4 or lowering the washing unit 7. By performing such a washing step, foreign matter adhering to the bottom surface of the polishing head 4 is removed.

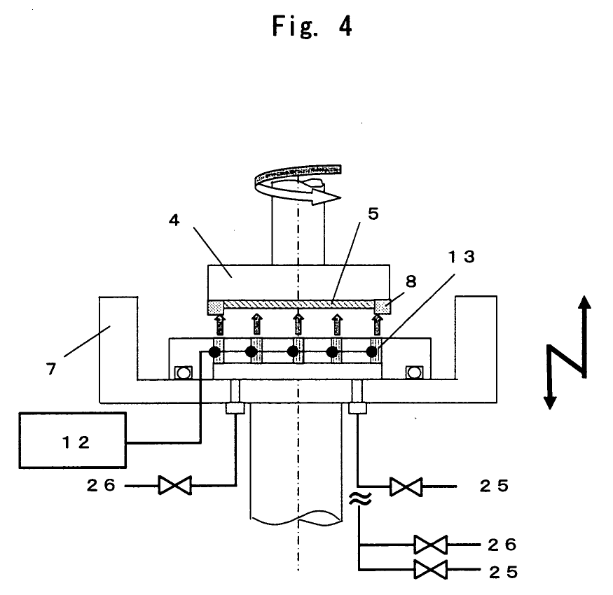

A fourth embodiment of the invention will be described with reference to FIG. 4. FIG. 4 is a schematic diagram of a polishing head washing unit according to the fourth embodiment of the invention. The washing unit is provided with not only the conventional polishing head washing mechanism but an additional washing mechanism using megasonic (ultrasonic) vibration (megasonic oscillation mechanism).

Unlike the first embodiment, the washing unit 7 is provided with the megasonic oscillation mechanism as a component which physically washes the wafer contact surface 5 and the retainer ring 8. The megasonic oscillation mechanism is provided with megasonic nozzles 13 formed in the washing unit 7 and an oscillator 12 connected to the megasonic nozzles 13. The megasonic nozzles 13 can be fixed at any positions. The other structure of the polishing head washing unit according to the fourth invention is the same as that described in the first embodiment, and the description of the same components as those described in the first embodiment will be omitted instead of giving the same reference numerals.

As for a method for washing the polishing head, like the washing method described in the first embodiment, the polishing head 4 is moved to the polishing head washing unit 7 before wafer loading or after wafer unloading. Thereafter, by lowering the polishing head 4 or raising the polishing head washing unit 7, the bottom surface of the polishing head 4 is covered with the polishing head washing unit 7. Then the DIW is supplied to the megasonic nozzles 13 while rotating the polishing head 4, and the ultrasonic vibrator within the megasonic nozzle 13 is oscillated to wash the bottom surface of the polishing head 4. Like FIG. 1, it is also possible to supply the chemical solution in addition to the DIW. The number of revolutions of the polishing head 4, the timing of the supplies of the DIW and the chemical solution, and the washing time of the polishing head 4 can be set freely as in the case of the polishing recipe of the CMP apparatus. Besides, it is possible to set the megasonic nozzles 13 of the polishing head washing unit 7 to any positions, so that the bottom surface of the polishing head 4 can be washed at concentrically selected places thereof. Furthermore, by pouring the DIW and the chemical solution into the polishing head washing unit 7, the megasonic washing can also be performed while dipping the polishing head 4 in the chemical solution. It is desirable that the chemical solution used for the washing lie in the same pH range or have the same pH value as the polishing slurry. After the washing, the polishing head 4 is brought into a stand-by state before wafer loading or after wafer unloading by raising the polishing head 4 or lowering the washing unit 7. By performing such a washing step, foreign matter adhering to the bottom surface of the polishing head 4 is removed.

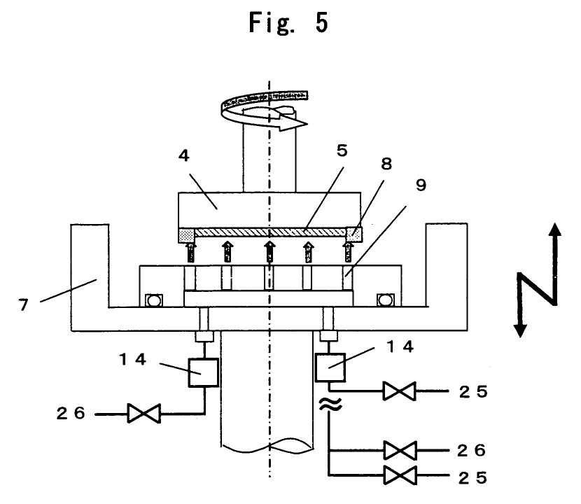

A fifth embodiment of the invention will be described with reference to FIG. 5. FIG. 5 is a schematic diagram of a polishing head washing unit according to the fifth embodiment of the invention. The washing unit is provided with not only the conventional polishing head washing mechanism but an additional washing mechanism using high-pressure spray (high-pressure spray mechanism).

Unlike the first embodiment of the invention, the washing unit 7 is provided with the high-pressure spray mechanism as a component which physically washes the wafer contact surface 5 and the retainer ring 8. The high-pressure spray mechanism includes high-pressure pumps 14 connected to the DIW lines 25 and the chemical solution lines 26.

With a method for washing the polishing head 4, like the washing method described in the first embodiment, the polishing head 4 is moved to the polishing head washing unit 7 before wafer loading or after wafer unloading. Thereafter, by lowering the polishing head 4 or raising the polishing head washing unit 7, the bottom surface of the polishing head 4 is covered with the polishing head washing unit 7. Then, while the polishing head 4 is rotated, the DIW is supplied to the spray nozzles 9 via the high-pressure pumps 14 to wash the bottom surface of the polishing head 4. Like FIG. 1, it is also possible to supply the chemical solution in addition to the DIW. The number of revolutions of the polishing head 4, the timing of the supplies of the DIW and the chemical solution, and the washing time of the polishing head 4 can be set freely as in the case of the polishing recipe of the CMP apparatus. Besides, the spray nozzles 9 of the polishing head washing unit 7 can be set to any positions, so that the bottom surface of the polishing head 4 can be washed at concentrically selected places thereof. Furthermore, by pouring the DIW and the chemical solution into the polishing head washing unit 7, high-pressure spray washing can also be performed in a state in which the polishing head 4 is dipped in the chemical solution. It is desirable that the chemical solution used for the washing lie in the same pH range or have the same pH value as the polishing slurry. After the washing, by raising the polishing head 4 or lowering the washing unit 7, the polishing head 4 is brought into a stand-by state before wafer loading or after wafer unloading. By performing such a washing step, foreign matter adhering to the bottom surface of the polishing head 4 is removed.

As described above, according to the embodiments of the invention, it is possible to almost completely remove the foreign matter adhering to the portion which holds the wafer to always keep the portion clean. Because of this, the ability of the washing unit to wash the backside of the wafer can be improved; hence, the occurrence of out-of-focus photolithography, abnormal polishing, and scratches is prevented by reducing residual particles on the backside of the wafer and residual particles on the frontside of the wafer resulting from the residual particles on the backside, and then, as effects of these results, not only device defects, such as leaks and short circuits between wirings, are prevented, but a wafer yield is improved. Besides, particle cross-contamination to an apparatus used in a post-CMP process step is prevented. Further, the washing cost of the wafer can be reduced by omitting a post-CMP washing process and washing process in its subsequent process and by reducing a load on the polishing apparatus. Still further, maintenance activities for the polishing head can be simplified by the adoption of a prolonged period between the maintenance activities and the use of an extended-life expendable polishing head material; hence, by these effects, it is expected that CoO (cost of ownership) is reduced. In addition, the number of times the washing process is performed is determined according to the number of times the polishing head is attached or detached or to a time period in which the wafers are polished, or the washing may be performed during the idling of the polishing apparatus.

What is claimed is:

1. An apparatus for polishing a semiconductor wafer comprising:
a wafer holder to which the wafer is attached;
a polishing unit which polishes the wafer with a polishing slurry supplied to the wafer;
a wafer attaching and detaching unit at which the wafer is attached to or detached from the wafer holder; and
a washing unit which washes the wafer holder,
the wafer holder having a wafer contact surface, which contacts the backside of the wafer, and a supporting unit which prevents the jump out of the wafer,
the washing unit having nozzles which supply a washing solution to the wafer contact surface and the supporting unit,
the nozzles are composed of a plurality of outlets capable of supplying at least two different liquids.

2. An apparatus for polishing a semiconductor wafer comprising:
a wafer holder to which the wafer is attached;
a polishing unit which polishes the wafer with a polishing slurry supplied to the wafer;
a wafer attaching and detaching unit at which the wafer is attached to or detached from the wafer holder; and
a washing unit which washes the wafer holder,
the wafer holder having a wafer contact surface, which contacts the backside of the wafer, and a supporting unit which prevents the jump out of the wafer,
the washing unit comprising nozzles, which supply a washing solution to the wafer contact surface and the supporting unit, and a component which physically washes the wafer contact surface and the supporting unit.

3. The apparatus for polishing a semiconductor wafer according to claim 1, wherein the washing unit is provided in the wafer attaching and detaching unit.

4. The apparatus for polishing a semiconductor wafer according to claim 2, wherein the washing unit is provided in the wafer attaching and detaching unit.

5. The apparatus for polishing a semiconductor wafer according to claim 1, wherein the washing solution is composed of water and a chemical solution.

6. The apparatus for polishing a semiconductor wafer according to claim 2, wherein the washing solution is composed of water and a chemical solution.

7. The apparatus for polishing a semiconductor wafer according to claim 1, wherein the washing solution is a chemical solution which lies in the same pH range or has the same pH value as the polishing slurry.

8. The apparatus for polishing a semiconductor wafer according to claim 2, wherein the washing solution is a chemical solution which lies in the same pH range or has the same pH value as the polishing slurry.

9. The apparatus for polishing a semiconductor wafer according to claim 1, wherein the nozzles concentrically supply the washing solution to the wafer contact surface of the wafer holder.

10. The apparatus for polishing a semiconductor wafer according to claim 2, wherein the nozzles concentrically supply the washing solution to the wafer contact surface of the wafer holder.

11. The apparatus for polishing a semiconductor wafer according to claim 2, wherein the physical washing component of the washing unit is an ultrasonic oscillation mechanism, a brush washing mechanism, a high-pressure spray mechanism, or a megasonic oscillation mechanism.

12. A method for polishing a semiconductor wafer, wherein a wafer holder, to which a wafer is attached, moves between a wafer attaching and detaching unit and a washing unit via a polishing unit to polish the semiconductor wafer and to wash the wafer holder and which comprises:
a step of attaching the wafer to the wafer holder at the wafer attaching and detaching unit and of conveying the wafer to the polishing unit;
a step of polishing the wafer through the use of the polishing unit, moving the polished wafer to the wafer attaching and detaching unit, and detaching the wafer from the wafer holder; and
a step of moving the wafer holder, from which the wafer has been detached, to the washing unit and of washing the wafer holder with at least two different liquids supplied.

13. The method for polishing a semiconductor wafer according to claim 12, wherein the washing unit washes the wafer holder through the use of an ultrasonic oscillation mechanism, a brush washing mechanism, a high-pressure spray mechanism, or a megasonic oscillation mechanism.

14. The method for polishing a semiconductor wafer according to claim 13, areas washed by the ultrasonic wave of the ultrasonic oscillation mechanism, the brush of the brush washing mechanism, the high-pressure spray of the high-pressure spray mechanism, or the megasonic vibration of the megasonic oscillation mechanism are each concentrically selected to the wafer contact surface of the wafer holder.

15. The method for polishing a semiconductor wafer according to claim 12, wherein the washing process is performed immediately before the wafer is attached or immediately after the wafer is detached.

16. The method for polishing a semiconductor wafer according to claim 12, wherein the number of times the washing process is performed is determined according to the number of times the wafer holder is attached or detached or to a time period in which the wafers are polished.

17. The method for polishing a semiconductor wafer according to claim 12, wherein the washing process is performed during the idling of the polishing apparatus.
